(19) United States
(12) Patent Application Publication
(10) Pub. No.: US 2026/0167483 A1
(43) Pub. Date: Jun. 18, 2026

(54) STACKED DIE WITH STEPPED SURFACE

(71) Applicant: InvenSense, Inc., San Jose, CA (US)

(72) Inventors: Jotaro Akiyama, Minami, Yamanashi Prefecture (JP); Daishi Arimatsu, Yamanashi-ken (JP); Yuki Shibano, Tokyo (JP)

(21) Appl. No.: 18/979,300

(22) Filed: Dec. 12, 2024

(51) Int. Cl. B81B 7/00; B81C 1/00

(52) U.S. Cl. CPC B81B 7/008; B81C 1/0023; B81B 2207/012; B81B 2207/07; B81B 2207/115; B81C 2203/0109; B81C 2203/0792

(57) ABSTRACT

A device includes a semiconductor layer, a micro-electro-mechanical systems (MEMS) device stacked on the semiconductor layer, and a package substrate. A step-shaped portion is formed on at least one exterior side of the MEMS device. The step-shaped portion includes a conductive layer formed thereon. The package substrate includes a wirebond pad, wherein a first wire electrically connects the semiconductor layer to the wirebond pad of the package substrate. A second wire electrically connects the conductive layer on the step-shaped portion of the MEMS device to the wirebond pad of the package substrate.

### BACKGROUND

Semiconductor device packages include one or more semiconductor devices or integrated circuits and may include devices such as a MEMS (“micro-electro-mechanical systems”) device, which is fabricated using semiconductor-like processes and exhibit mechanical characteristics. In many cases, such as in motion products, MEMS devices interact with electrical signals. For example, a MEMS device may optionally include electronics for sensing. Examples of such MEMS devices include, but are not limited to, gyroscopes, inertial measurement units (IMUs), accelerometers, pressure sensors, etc.

MEMS devices can also be formed by stacking or bonding a MEMS layer to a Semiconductor layer. Optionally, the semiconductor layer may include circuitries that may process signals, e.g., sensing signals, received from the MEMS device. Such MEMS devices may utilize wire bonding to establish an electrical connection between the MEMS device and the package substrate, e.g., ground connection. Techniques for wire bonding include, but are not limited to, wedge bonding and ball bonding.

Current methodologies for wire bonding a MEMS device to the package substrate include wire bonding from a surface of the MEMS layer that faces away from the package substrate. Unfortunately, the wire loop height should be accounted for when the MEMS device is being packaged and goes through the molding process. Unfortunately, since the wirebond is a loop from the upper portion surface of the MEMS layer, it adds to the distance required between the MEMS layer and the mold compound surface of the semiconductor package. A current solution to this problem includes making the cap layer thinner to shorten the height, which unfortunately exposes the stacked device to mechanical bending resulting from external stress. In some conventional systems, the thickness of the mold compound margin is reduced over the wirebond loop, which may adversely impact the robustness of the system, e.g., exposing the stacked device to mechanical bending when an external stress is applied.

### SUMMARY

Accordingly, a need has arisen to connect the MEMS device stacked on a CMOS layer to a package substrate in such a way to improve robustness against external stress, such as mechanical bending. The embodiments as described below enables the MEMS device to have a thicker cap layer to improve robustness (e.g., reduce adverse impact of external stress and mechanical bending) while reducing the height requirement of a wirebond connecting the MEMS device to the package substrate.

In some embodiments, a device includes a semiconductor layer, a micro-electro-mechanical systems (MEMS) device stacked on the semiconductor layer, and a package substrate. A step-shaped portion is formed on at least one exterior side of the MEMS device. The step-shaped portion includes a conductive layer formed thereon. The package substrate includes a wirebond pad, wherein a first wire electrically connects the semiconductor layer to the wirebond pad of the package substrate. A second wire electrically connects the conductive layer on the step-shaped portion of the MEMS device to the wirebond pad of the package substrate.

In some embodiments, the MEMS device includes a cap layer and a MEMS device layer, wherein the step-shaped portion is formed in the cap layer, and wherein the cap layer includes a cavity formed therein. In one nonlimiting example the MEMS device is eutectically bonded to the semiconductor layer. According to some embodiments, the wirebond pad facilitates a ground connection to the MEMS device and to the semiconductor layer. In some embodiments, the device further includes a molding compound formed over the wirebond pad of the package substrate and further on the step-shaped portion of the MEMS device. In one nonlimiting example, the device further includes a second semiconductor layer (interposer) disposed over the package substate and attached to the semiconductor layer. According to some embodiments, a third wire that electrically connects the second semiconductor layer to the wirebond pad. In one nonlimiting example, the device includes a third wire that electrically connects the semiconductor layer to a through-silicon-via (TSV) formed in the second semiconductor layer. The TSV is electrically connected to the package substrate by a flip chip bump. According to some embodiments, the semiconductor layer is attached to the package substrate by a second die-attach and electrically connected by a flip-chip bump.

In some embodiments, a device includes a first semiconductor layer, a second semiconductor layer, a micro-electro-mechanical systems (MEMS) device, and a package substrate. The second semiconductor layer includes an application specific integrated circuit (ASIC). The MEMS device is stacked on the second semiconductor layer (interposer), wherein a step-shaped portion is formed on at least one exterior side of the MEMS device, and wherein the step-shaped portion includes a conductive layer formed thereon. The package substrate includes a wirebond pad, wherein a first wire electrically connects the second semiconductor layer to the wirebond pad of the package substrate. A second wire electrically connects the first semiconductor layer to the second semiconductor layer. A third wire electrically connects the second semiconductor layer to the conductive layer on the step-shaped portion of the MEMS device.

In one nonlimiting example, the first semiconductor layer is attached to the package substrate by a first die attach and the second semiconductor layer is attached to the package substrate by a second die attach. The device may include a molding compound formed over the wirebond pad of the package substrate and further on the step-shaped portion of the MEMS device. According to some embodiments, the first semiconductor layer comprises metal routing and second semiconductor comprises CMOS. In one nonlimiting example, the step-shaped portion is formed in the cap layer.

According to some embodiments, a method includes forming a photoresist on an exterior surface of a micro-electro-mechanical systems (MEMS) device. The MEMS device is bonded to a semiconductor layer from a side opposite of the exterior surface of the MEMS device, wherein the MEMS device bonded to the semiconductor layer forms a stacked device. The method further includes patterning the photoresist on the exterior surface of the MEMS device to expose a portion of the MEMS device. According to some embodiments, the method further includes etching the exposed portion of the MEMS device to form a step-shaped portion on the exterior surface of the MEMS device. In one nonlimiting example, the method also includes removing the photoresist on the exterior surface of the MEMS device and forming a conductive layer on the exterior surface of the MEMS device including the step-shaped portion. The method further includes dicing through a portion of the step-shaped portion and through the semiconductor layer to form at least two separate stacked devices.

According to some embodiments, the method further includes positioning one stacked device of the two separate stacked device on a package substrate. In one nonlimiting example, the package substrate includes a wirebond pad, and wherein the method further includes attaching a wire from the step-shaped portion of the one stacked device to the wirebond pad. The method may further include attaching another wire from the semiconductor layer to the wirebond pad. It is appreciated that the wirebond pad provides a ground to the MEMS device of the one stacked device and the semiconductor layer. According to some embodiments, the method further includes forming a molding compound over the wirebond pad of the package substrate and further on the step-shaped portion of the MEMS device. It is appreciated that the MEMS device is eutetically bonded to the semiconductor layer. According to some embodiments, the MEMS device includes a cap layer and a MEMS device layer, and wherein the step-shaped portion is formed in the cap layer, and wherein the cap layer includes a cavity formed therein.

These and other features and advantages will be apparent from a reading of the following detailed description.

### BRIEF DESCRIPTION OF DRAWINGS

FIG. 1 shows a stacked MEMS device on a CMOS device according to one aspect of the present embodiments.

FIGS. 2-6 show a fabrication process for creating a stacked MEMS device on a CMOS device according to one aspect of the present embodiments.

FIG. 7 shows a two stacked MEMS devices according to one aspect of the present embodiments.

FIG. 8 shows a stacked CMOS on a MEMS device according to another aspect of the present embodiments.

FIG. 9 shows a flow diagram for fabricating a stacked MEMS device on a CMOS device according to one aspect of the present embodiments.

FIGS. 10-12 show a device including a MEMS device stacked on top of an interposer that is stacked on top of a CMOS that are electrically connected to a package substrate in accordance with some embodiments.

FIG. 13 shows a stacked MEMS device on top of an interposer positioned on a package substrate and a CMOS device that is electrically connected to the MEMS device and the interposer and further electrically connected to the package substrate in accordance with some embodiments.

### DESCRIPTION

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein.

It should also be understood that the terminology used herein is for the purpose of describing the certain concepts, and the terminology is not intended to be limiting. Unless defined otherwise, all technical and scientific terms used herein have the same meaning as commonly understood in the art to which the embodiments pertain.

Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “beside,” “forward,” “reverse,” “overlying,” “underlying,” “up,” “down,” or other similar terms such as “upper,” “lower,” “above,” “below,” “under,” “between,” “over,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Terms such as “over,” “overlying,” “above,” “under,” etc., are understood to refer to elements that may be in direct contact or may have other elements in-between. For example, two layers may be in overlying contact, wherein one layer is over another layer and the two layers physically contact. In another example, two layers may be separated by one or more layers, wherein a first layer is over a second layer and one or more intermediate layers are between the first and second layers, such that the first and second layers do not physically contact.

A need has arisen to connect the MEMS layer stacked on a CMOS layer (or a routing layer) to a package substrate in such a way to improve robustness against external stress, such as mechanical bending. The embodiments as described below enables the MEMS layer to have a thicker cap layer to improve robustness (e.g., reduce adverse impact of external stress and mechanical bending) while reducing the height requirement of a wirebond connecting the MEMS layer to the package substrate. Alternatively, the embodiments described below allow for the cap layer to retain a reduced thickness while simultaneously reducing the overall package size.

A MEMS device may include a MEMS layer coupled to a semiconductor layer, such as a CMOS. The MEMS layer may include a cap layer, a conductive metal layer, a MEMS device layer, and a bonding layer. In some examples, the MEMS device layer may be coupled to the cap layer through a fusion bond layer. The MEMS device layer may commonly be referred to as the actuator layer with movable structures. The cap layer coupled to the MEMS device layer may form one or more cavities associated with accelerometer or other sensing applications. The MEMS layer may also include a bonding layer, allowing the MEMS layer to be bonded to a semiconductor layer such as a CMOS. Once the MEMS layer and CMOS are coupled together, a stacked device is formed and can be placed on top of and connected to a package substrate. It is appreciated that a wirebond may be used in order to electrically couple the MEMS layer to the package substrate. CMOS may similarly be electrically coupled to the package substrate.

It is appreciated that according to some embodiments, the upper surface of the stacked die may be step-shaped. In other words, the MEMS layer that forms the upper portion of the stacked die may be etched to form the step-shaped portion. The step-shaped portion may be coated with a conductive material. As such, the wirebond may be used to make electrical connection from the conductive layer formed on the step-shaped portion of the MEMS layer to the package substrate. It is appreciated that since the step-shaped portion reduces a thickness of only a portion of the cap layer where the wirebond is connected, it can reduce the height associated with the loop (the wire). As such, the need to take the height of the loop (wirebond) into account is eliminated or consideration associated with the height of the loop is reduced. In one nonlimiting example, the thickness of the cap layer can be maximized for a given package mold thickness. Additionally, the robustness of the device remains unimpacted (e.g., to external stress and mechanical bending) since the need to thin the cap layer to address the height associated with the wirebond loop is reduced or eliminated. It is appreciated that similarly the need to account for the height of the wirebond loop is eliminated in a stacked die where the upper layer is CMOS and the lower layer is a MEMS layer by forming a step-shaped portion on the CMOS layer. It is further appreciated that, even if the wire in the wire bond goes above the height of the MEMS device, the step-shaped structure will nonetheless reduce the headroom needed to account for the wire and as a result reduce the overall package thickness.

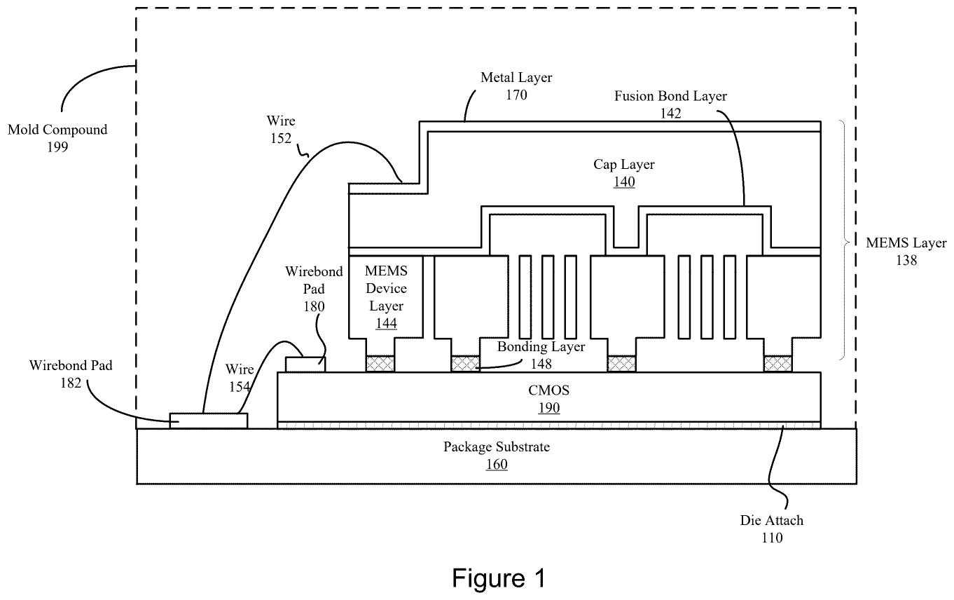

Referring now to FIG. 1, a stacked die including a MEMS layer 138 stacked on a semiconductor layer, e.g., CMOS 190, according to some embodiments is shown. It is appreciated that while the embodiments are described with respect to the CMOS 190 for illustrative purposes, the embodiments should not be construed as limited thereto. For example, the embodiments are equally applicable to a routing layer for routing connections between two dies. The MEMS layer 138 has two surfaces or sides depicted (opposite to one another). A first surface faces the CMOS 190 semiconductor layer that the MEMS layer 138 is bonded to (also referred to as the “interior” surface), and a second surface that faces away from the CMOS 190 (e.g., opposite to the first surface) and toward the outer mold compound 199 (also referred to as the “exterior” surface). The MEMS layer 138 may include a cap layer 140 and a MEMS device layer 144. The cap layer 140 (e.g., Si) may be coupled to the MEMS device layer 144 using a fusion bond layer 142, e.g., SiO₂, and may form cavities that can be associated with sensing applications such as an accelerometer. The MEMS device layer 144 may be referred to as the actuator layer with movable structures that in response to a stimuli, e.g., acceleration, pressure, etc., can convert the mechanical movement into electrical signal, thereby sensing the external stimuli. In one nonlimiting example, the fusion bond layer 142 forms on the interior side of the cap layer 140 couples the cap layer 140 to the MEMS device layer 144. In accordance with some embodiments, the exterior surface of the MEMS layer 138 is etched to form a step-shaped portion structure of the MEMS layer 138. It is appreciated that the step-shaped portion faces away from the interior surface since the exterior surface and the interior surfaces are on opposite surfaces of the cap layer 140. According to some embodiments, a metal layer 170 is deposited over the exterior surface of the cap layer 140 after the cap layer 140 is etched. In one nonlimiting example, the metal layer 170 is deposited on the step-shaped portion whereas in another nonlimiting example, the metal layer 170 is deposited over the entire exterior surface (including the step-shaped portion), as discussed in further detail below.

The MEMS layer 138 may further include a bonding layer 148, such as Al, AlCu, Germanium, etc., for bonding the MEMS layer 138 to the CMOS 190 layer. The bonding layer 148 allows the MEMS layer 138 to be bonded to the semiconductor layer, e.g., CMOS 190 layer to form the stacked die. In one nonlimiting example, the interior surface of the MEMS layer 138 may be eutectically bonded to the CMOS 190. For example, the bonding layer 142 may include Aluminum on one substrate and Germanium on the second substrate to eutectically bond the MEMS layer 138 to the CMOS 190 layer. The eutectic bond is formed by bonding the aluminum to the germanium at particular temperatures, thereby forming a hermetic seal and providing an electrical connection.

It is appreciated that the stacked die including the MEMS layer 138 stacked on top of CMOS 190 may be positioned on and connected to a package substrate 160 (e.g., Si, etc.). In accordance with some embodiments, a die attach 110 may be used to attach the CMOS 190 to the package substrate 160. The package substrate 160 can be used to transmit electrical signals to/from the stacked die, including the MEMS layer 138 and/or the CMOS 190 layer. In one nonlimiting example, the package substrate 160 may provide a ground terminal to the stacked die using its wirebond pad 182. In some nonlimiting examples, wire bonding can be achieved through wedge bonding or ball bonding. The wirebond pad 182 can be used to facilitate an electrical connection (e.g., ground) to the MEMS layer 138 (e.g., metal layer 170 on the step-shaped portion of the MEMS layer 138) and further to the CMOS 190 layer (e.g., wirebond pad 180 of the CMOS 190 layer) through wires 152 and 154 respectively. The CMOS 190 may include a wirebond pad 180 on the surface facing the MEMS layer 138. The wirebond pad 180 can be used to electrically connect the CMOS 190 to the wirebond pad 182 of the package substrate 160, via wire 154. The wire 152 can electrically connect the wirebond pad 182 of the package substrate 160 to the conductive metal layer 170 of the MEMS layer 138 of the step-shaped portion of the cap layer 140. It is appreciated that using same wirebond bond 182 on the package substrate 160 to connect to both the MEMS layer 138 and the CMOS 190 layer is provided for illustrative purposes and should not be construed as limiting the scope of the embodiments. For example, in one nonlimiting examples, the package substrate 160 may have one wirebond pad associated with the MEMS layer 138 and may have a different wirebond pad associated with CMOS 190 layer.

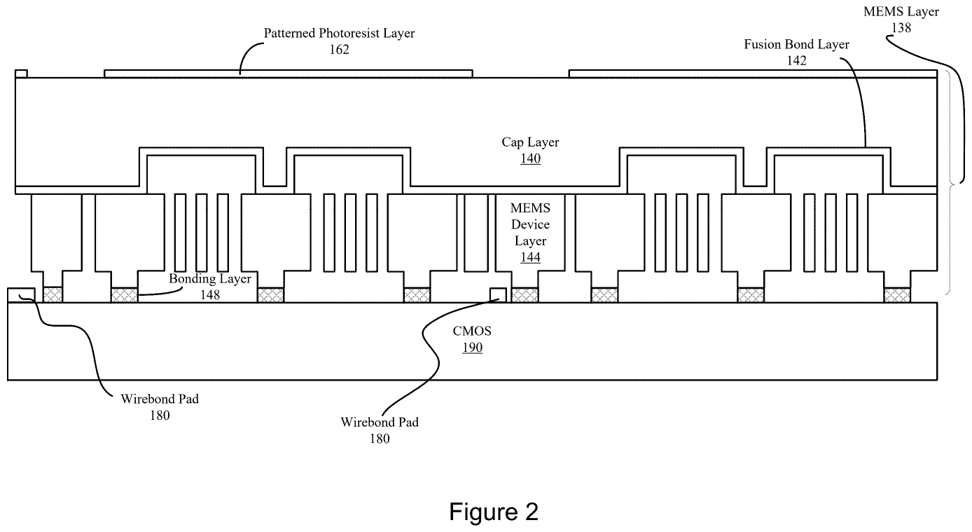

In one nonlimiting example, the wire 152 is connected to the exterior surface of the MEMS layer 138, particularly the exterior surface of the step-shaped portion of the MEMS layer 138 coated with metal layer 170. It is appreciated that, by creating the step-shaped structure in the MEMS layer 138, the wires will not hang on to the top surface of the MEMS layer 138, thereby reducing headroom and the overall size of the package. It is also appreciated that, by creating the step-shaped structure in the MEMS device 138, the overall package thickness may be decreased while maintaining or improving robustness, e.g., mechanical bending due to external stress. For example, a MEMS layer 138 (e.g., the cap layer 140) without the step-shaped portion results in a larger headroom requirement due to the height associated with the wire 152 and as such in a larger (e.g., thicker) package form factor. Furthermore, it is appreciated that the creation of the step-shaped structure can eliminate the need for a notch cut in the tab dicing process because the step-shaped structure on the MEMS layer 138 can be used as the alignment mark for purposes of tab dicing, as exemplified further below with respect to FIGS. 2-6.

It is appreciated that, in accordance with some embodiments, a molding compound 199 may be formed over the exterior surface of the MEMS layer 138, e.g., the step-shaped portion of the MEMS layer 138, as well as the wirebond pad 182 of the package substrate 160, exposed regions of the package substrate 160, and/or the exposed regions of the CMOS 190 layer (surface regions facing the interior surface of the MEMS layer 138 that are not covered by the MEMS layer 138). In one nonlimiting example, the molding compound 199 may be an epoxy molding compound (EMC).

FIGS. 2-6 depict a fabrication process for stacked MEMS device on a CMOS device according to one aspect of the present embodiments. Referring now to FIG. 2, a MEMS layer 138 is bonded to a CMOS 190 layer forming a stacked die device. The CMOS 190 may include multiple wirebond pads, e.g., two wirebond pads 180 on the side facing the MEMS layer 138. The MEMS layer 138 may include a cap layer 140, a MEMS device layer 144, a fusion bond layer 142, and a bonding layer 148 (similar to FIG. 1 and as described in detail above). In accordance with some embodiments, a photoresist layer is formed over the MEMS layer 138 and is patterned to form the patterned photoresist layer 162 on the exterior surface of the cap layer 140. The patterned photoresist layer 162 leaves certain portions (on the exterior surface) of the cap layer 140 exposed (e.g., areas on the exterior surface of the cap layer 140 that is not covered by the photoresist). The exposed portions of the cap layer 140 (portions of the exterior surface of the cap layer 140 that are not covered by the patterned photoresist layer 162) demarcate where the step-shaped structure will be etched into the cap layer 140.

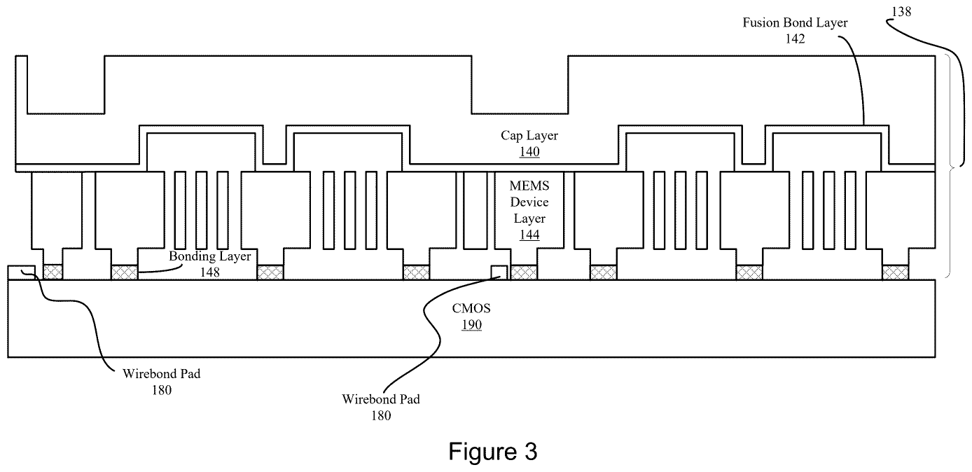

Referring now to FIG. 3, the exposed portions of the cap layer 140 are etched away to form two step-shaped structures in the exterior surface of the MEMS layer 138, e.g., step-shaped structure formed within the cap layer 140. After the step-shaped structures are etched into the cap layer 140, the patterned photoresist layer 162 may be removed from the exterior surface of the cap layer 140, leaving the exterior surface of the MEMS layer 138 (exterior surface of the cap layer 140) exposed.

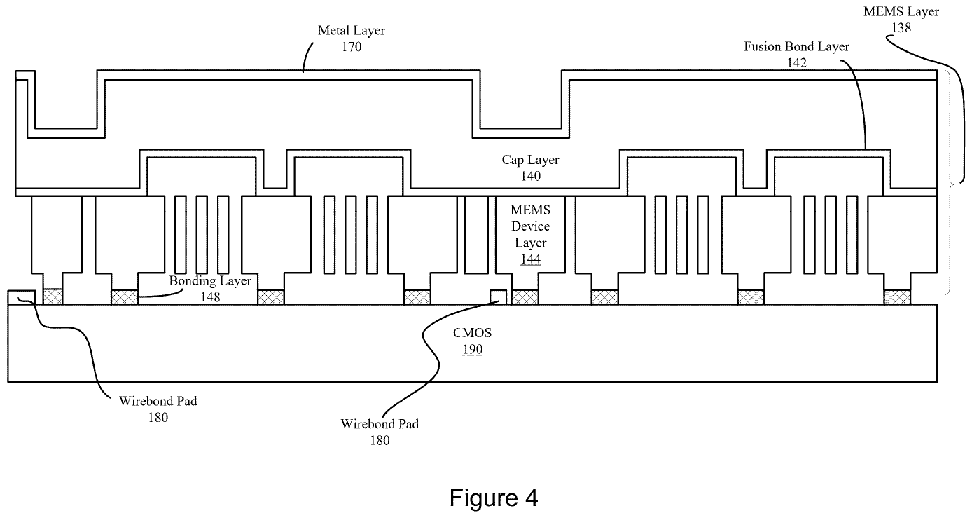

Referring now to FIG. 4, a conductive layer such as metal layer 170 may be formed on the exterior surface of the MEMS layer 138 (particularly, on the exterior surface of the cap layer 140), including the step-shaped structures that was formed via the etching process into the cap layer 140. As described above with respect to FIG. 1, in accordance with one nonlimiting example, the metal layer 170 may be AlCu. By placing the conductive metal layer 170 over the exterior surface of the cap layer 140, an electrical connection can later be established between the MEMS layer 138 and the package substrate by wire bonding the metal layer 170 formed on the step-shaped region of the MEMS layer 138 to the package substrate.

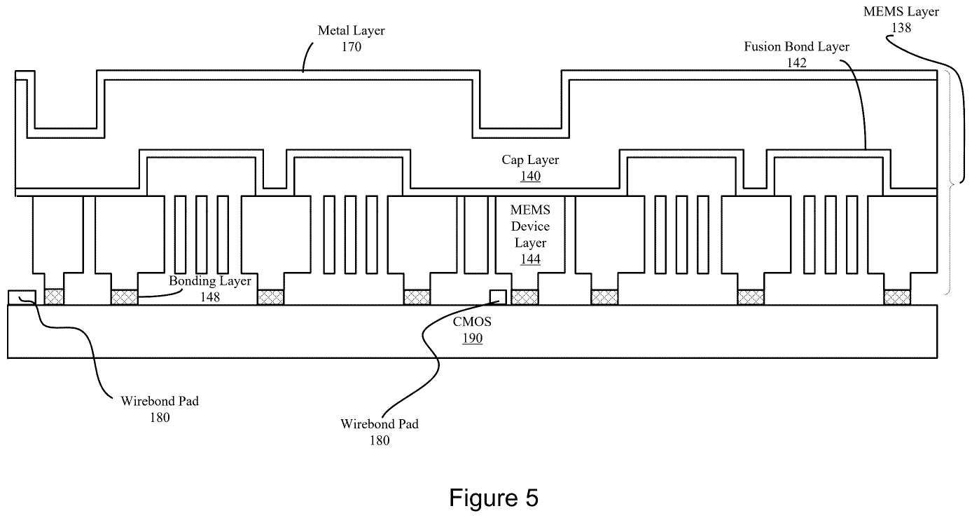

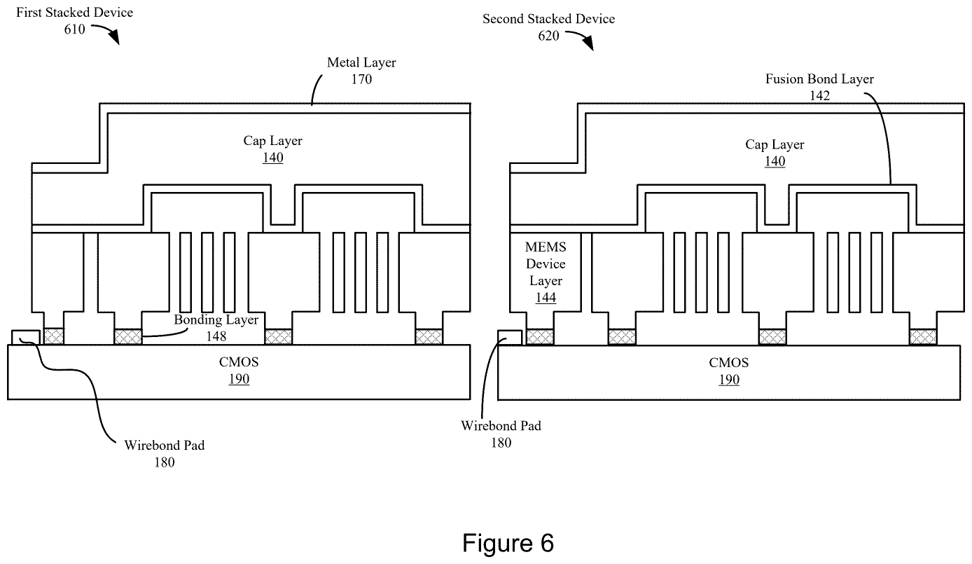

Referring now to FIG. 5, the semiconductor layer (in this case, CMOS 190) may be thinned subsequent to the metal layer 170 being formed on the exterior surface of the MEMS layer 138. Referring now to FIG. 6, the step-shaped structures etched into the cap layer 140 of the stacked device may be diced through (and going through the CMOS 190 layer) to create multiple stacked dies, each with its a step-shaped portion formed on the exterior surface of their cap layer 140. It is appreciated that the step-shaped structures formed into the cap layer 140 reduce the need to rely on a notch cut in the tab dicing process. Instead, as shown through FIGS. 5 and 6, the step-shaped structure itself acts as the alignment mark as dicing through one side creates the step-shaped portion in the cap layer 140. In accordance with some embodiments, the result is a first stacked device 610 and a second stacked device 620. Similar to FIG. 1, both the first stacked device 610 and the second stacked device 620 include a MEMS layer 138 coupled to a CMOS 190 layer, with a step-shaped structure etched in the exterior surface of the MEMS layer 138, particularly the cap layer 140. It is appreciated that description of the stacked device (MEMS layer on a CMOS layer) is provided for illustrative purposes and should not be construed as limiting the scope of the embodiments. For example, as described further below, a CMOS may be stacked on top of a MEMS, a MEMS may be stacked on top of another MEMS, etc.

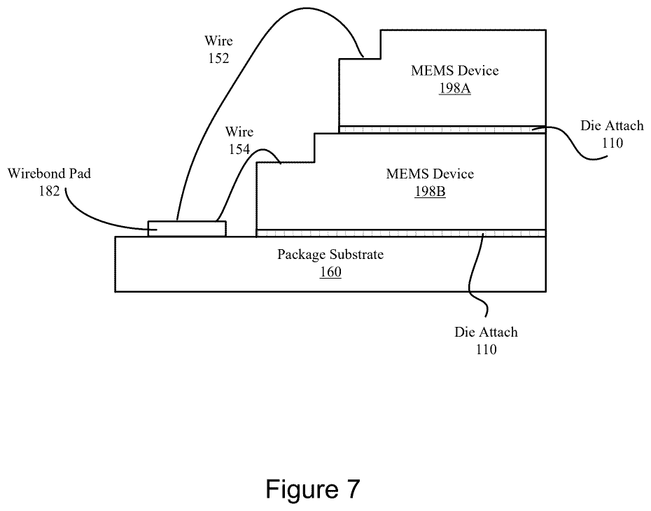

Referring now to FIG. 7, two MEMS devices are stacked on top of each other and electrically connected to a package substrate. It is appreciated that the MEMS device 198A and the MEMS device 198B may be similar to the MEMS layer 138 previously discussed above and found in FIG. 1. In accordance with FIG. 7, both the MEMS devices 198A and 198B have a step-shaped structure as previously discussed above. In accordance with some embodiments, two die attaches may be used. A first die attach 110 may be used to attach MEMS device 198A to MEMS device 198B, and a second die attach 110 may be used to attach MEMS device 198B to the package substrate 160. The package substrate 160 can be electrically connected to both MEMS devices 198A and 198B by using wires 152 and 154 to electrically connect the step-shaped portion of the MEMS device 198A and 198B to the wirebond pad 182 respectively. It is appreciated that, by etching a step-shaped structure into both MEMS devices 198A and 198B, the height requirement associated with the wires 152 and 154 can be hidden within that step-shaped portion and thereby allow the MEMS layers to retain the thickness of each of their cap layers (the non-step-shaped portions) and increase their robustness.

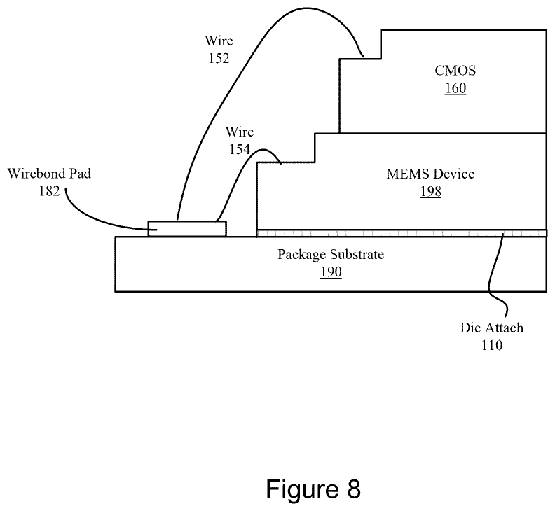

Referring now to FIG. 8, another embodiment is shown where a CMOS is stacked on top of a MEMS device and both are electrically connected to a package substrate. Once again, the MEMS device 198 may be similar to the MEMS layer 138 discussed above and found in FIG. 1. The MEMS layer 198 may be attached to the package substrate 160 using a die attach 110. It is appreciated that a step-shaped structure can be etched in the CMOS 190, in a similar manner as discussed above with respect to FIGS. 2-6. In accordance with the embodiment in FIG. 8, the CMOS 190 and the MEMS device 198B may be electrically connected to the package substrate 160 using the wirebond pad 182 through the wires 152 and 154, respectively (as discussed above with respect to FIGS. 1 and 7). It is appreciated that, by etching a step-shaped structure in the CMOS 160, the wire 152 can similarly be hidden within the step-shaped portion and eliminate the need to account for the height associated with the wire loop, as described above.

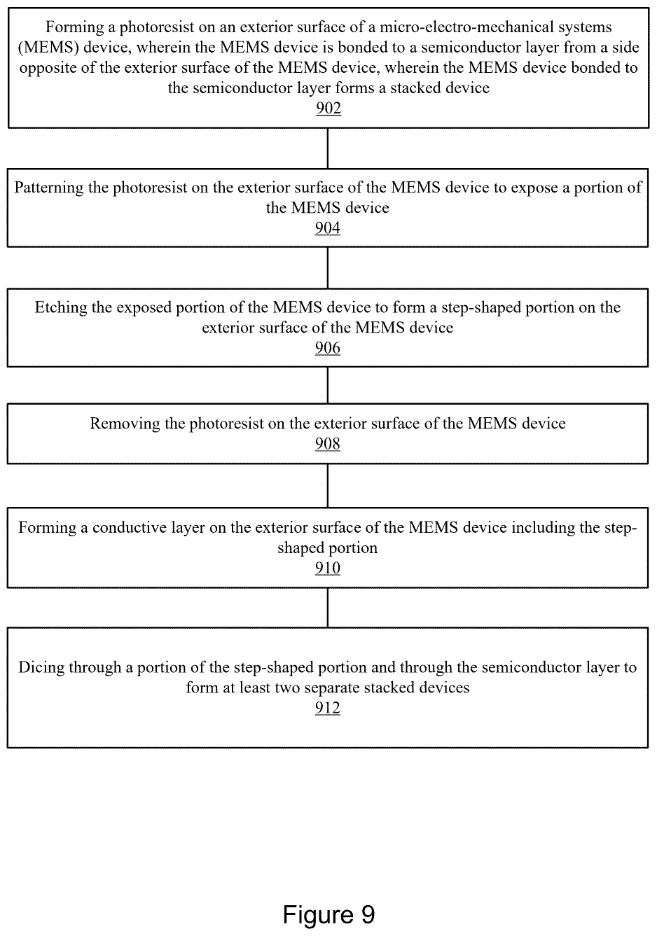

Referring now to FIG. 9, a flow diagram for fabricating a stacked MEMS device on a CMOS device is shown and as described in FIGS. 2-6. At step 902, a photoresist is formed on an exterior surface of a MEMS device. The MEMS device is bonded to a semiconductor layer from a side opposite the exterior from a side opposite the exterior surface of the MEMS device. The MEMS device bonded to the semiconductor layer forms a stacked device, as described above. At step 904, the photoresist on the exterior side of the MEMS device is patterned to expose a portion of the MEMS device, as discussed above. At step 906, the exposed portion of the MEMS device is etched to form a step-shaped portion on the exterior surface of the MEMS device, as discussed above. At step 908, the photoresist on the exterior surface of the MEMS device is removed, as discussed above. At step 910, a conductive layer is formed on the exterior surface of the MEMS device, including the step-shaped portion, as discussed above. At step 912, a portion of the step-shaped portion and a portion of the semiconductor layer are diced through to create two separate stacked devices, as discussed above.

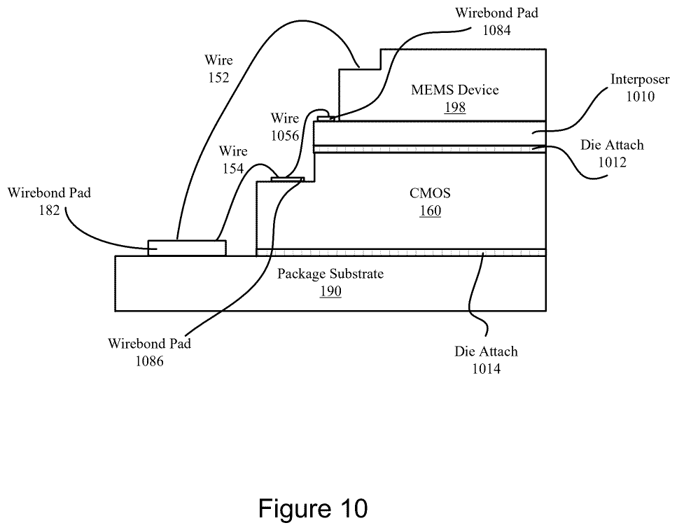

Referring now to FIG. 10, another embodiment is shown where a MEMS device 198 is stacked on top of a CMOS 160 with an interposer. Components with element numbers that are the same as those descried in preceding figures operate similar as those described above. In one nonlimiting example, the MEMS device 198 stacked on top of the CMOS 160 and are electrically connected to a package substrate. The MEMS device 198 and CMOS 160 are similar to the MEMS devices and CMOS found in FIGS. 1 and 8. In accordance with some embodiments, an interposer 1010 may be used to couple the MEMS device 198 to the CMOS 160. Similar to FIGS. 1, 7, and 8 as discussed above, a die attach 1012 may be used to couple the interposer 1010 to CMOS 160, and a die attach 1014 may be used to couple the CMOS 160 to the package substrate 190. In one nonlimiting example, a first wire 152 may be used to connect the step-shaped portion of the exterior conductive layer of MEMS device 198 to the wirebond pad 182 of the package substrate 190 in order to establish an electrical connection between the MEMS device 198 and the package substrate 190. A second wire 154 may connect the wirebond pad 1086 on the CMOS to the wirebond pad 182 of the package substrate 190 in order to establish an electrical connection between the CMOS 160 and the package substrate 190. A third wire 1056 may be used to electrically connect the interposer 1010 using the wirebond pad 1084 to the wirebond pad 1086 of the CMOS 160 in order to establish an electrical connection between the interposer 1010 and the CMOS 160.

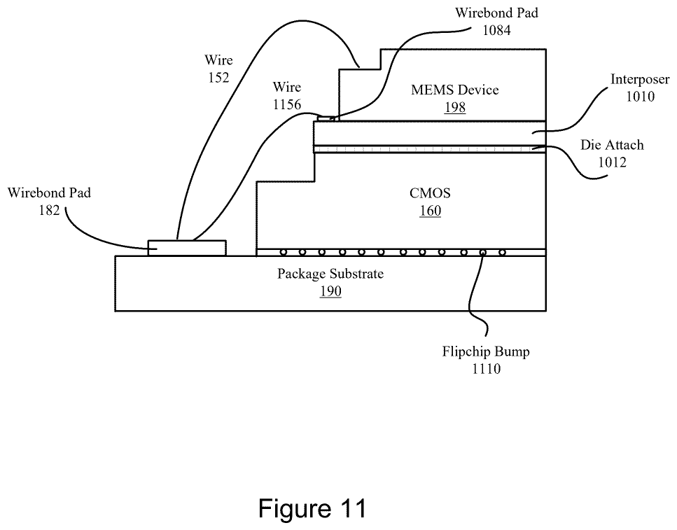

In accordance with other embodiments, CMOS 160 may be coupled to the package substrate 190 without the use of a die attach and may be electrically coupled without the use of a wirebond connection. Referring now to FIG. 11, in one nonlimiting example, CMOS 160 may be coupled to the package substrate 190 using a flip-chip bump 1110. The flip-chip bump 1110 may be used to establish electrical connection between the CMOS 160 and the package substrate 190 instead of using a wirebond connection. In this nonlimiting example, the interposer 1010 may be electrically coupled to the package substrate 190 using wire 1156 coupled to the wirebond pad 1084 of the interposer 1010 to the wirebond pad 182 of the package substrate 190. In other words, in some examples, the interposer 101 may be electrically coupled to the package substrate using wire 1156 instead of being electrically coupled to the CMOS 160, as was the case in FIG. 10.

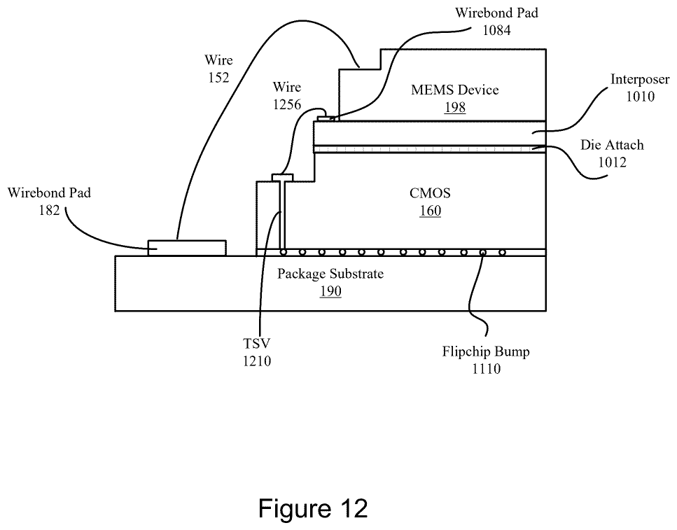

Referring now to FIG. 12, another nonlimiting example for electrically coupling the interposer to the CMOS and the package substrate according to some embodiments is shown. Electrical signals from the interposer 1010 may be transmitted to the CMOS 160. For example, a wire 1256 may be coupled to the wirebond pad 1084 on the interposer 1010 form one end and may connect to a through-silicon via (TSV) 1210 formed within the CMOS 160 on the other end. As such, electrical signals may be routed from the interposer 1010 to the CMOS 160 using the wire 1256 and from one side of the CMOS 160 to the other side of the CMOS 160 using the TSV 1210 and finally from the CMOS 160 to the package substrate 190 using flipchip bump 1110.

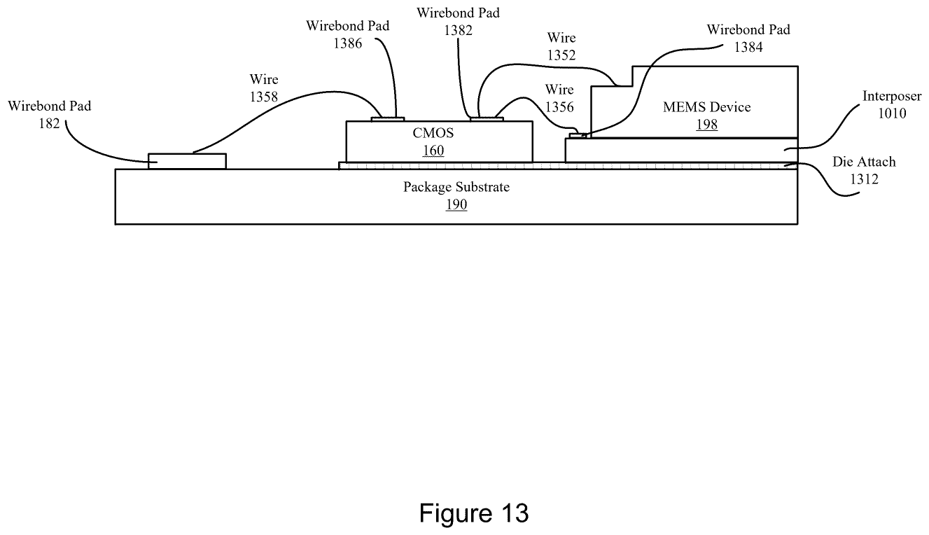

Referring now to FIG. 13, a step-shaped MEMS device and a CMOS positioned on a package substrate in a non-stacked formation according to some embodiments is shown. In one nonlimiting example, the step-shaped MEMS device 198 may be coupled (stacked) on the interposer 1010 and coupled to the package substrate 190 using a die attach 1312. In an example, the CMOS 160 may be coupled to the package substrate 190 using the die attach 1312. It is appreciated that the MEMS device 198 and the CMOS 160 in this configuration are not stacked on top of one another unlike the embodiments described above. According to some examples, electrical signals from the MEMS device 198 may be routed to the CMOS 160. For example, the wire 1352 may connect to the step-shaped portion of the MEMS device 198 from one end and connect to the wirebond pad 1382 on the CMOS 160 from the other end in order to rout electrical signals from the MEMS device 198 to the CMOS 160. Similarly, electrical signals from the interposer 1010 may be routed to the CMOS 160. For example, the wire 1356 may connect to the wirebond pad 1384 of the interposer 1010 from one end and connect to the wirebond pad 1382 on the CMOS 160 from the other end in order to rout electrical signals from the interposer 1010 to the CMOS 160. Electrical signals may be routed from the CMOS 160 to the package substrate 190. For example, the wire 1358 may connect to the wirebond pad 1386 of the CMOS 160 from one side and may connect to the4 wirebond pad 182 of the package substrate 190 from the other side in order to route electrical signals from the CMOS 160 to the package substrate 190.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. A device comprising:
a semiconductor layer;
a micro-electro-mechanical systems (MEMS) device stacked on the semiconductor layer, wherein a step-shaped portion is formed on at least one exterior side of the MEMS device, and wherein the step-shaped portion includes a conductive layer formed thereon; and
a package substrate comprising a wirebond pad, wherein a first wire electrically connects the semiconductor layer to the wirebond pad of the package substrate, and wherein a second wire electrically connects the conductive layer on the step-shaped portion of the MEMS device to the wirebond pad of the package substrate.

2. The device of claim 1, wherein the MEMS device includes a cap layer and a MEMS device layer, wherein the step-shaped portion is formed in the cap layer, and wherein the cap layer includes a cavity formed therein.

3. The device of claim 1, wherein the MEMS device is eutectically bonded to the semiconductor layer.

4. The device of claim 1, wherein the wirebond pad facilitates a ground connection to the MEMS device and to the semiconductor layer.

5. The device of claim 1 further comprising a molding compound formed over the wirebond pad of the package substrate and further on the step-shaped portion of the MEMS device.

6. The device of claim 1, further comprising a second semiconductor layer (interposer) disposed over the package substate and attached to the semiconductor layer.

7. The device of claim 6, further comprising a third wire that electrically connects the second semiconductor layer to the wirebond pad.

8. The device of claim 6, further comprising a third wire that electrically connects the semiconductor layer to a through-silicon-via (TSV) formed in the second semiconductor layer.

9. The device of claim 8, wherein the TSV is electrically connected to the package substrate by a flip chip bump.

10. The device of claim 1, wherein the semiconductor layer is attached to the package substrate by a second die-attach and electrically connected by a flip-chip bump.

11. A device comprising:
a first semiconductor layer;
a second semiconductor layer including an application specific integrated circuit (ASIC);
a micro-electro-mechanical systems (MEMS) device stacked on the second semiconductor layer (interposer), wherein a step-shaped portion is formed on at least one exterior side of the MEMS device, and wherein the step-shaped portion includes a conductive layer formed thereon;
a package substrate comprising a wirebond pad, wherein a first wire electrically connects the second semiconductor layer to the wirebond pad of the package substrate, and
wherein a second wire electrically connects the first semiconductor layer to the second semiconductor layer;
wherein a third wire electrically connects the second semiconductor layer to the conductive layer on the step-shaped portion of the MEMS device.

12. The device of claim 11, wherein the first semiconductor layer is attached to the package substrate by a first die attach and the second semiconductor layer is attached to the package substrate by a second die attach.

13. The device of claim 11 further comprising a molding compound formed over the wirebond pad of the package substrate and further on the step-shaped portion of the MEMS device.

14. The device of claim 11, wherein the first semiconductor layer comprises metal routing and second semiconductor comprises CMOS.

15. The device of claim 11, wherein the step-shaped portion is formed in the cap layer.

16. A method comprising:
forming a photoresist on an exterior surface of a micro-electro-mechanical systems (MEMS) device, wherein the MEMS device is bonded to a semiconductor layer from a side opposite of the exterior surface of the MEMS device, wherein the MEMS device bonded to the semiconductor layer forms a stacked device;
patterning the photoresist on the exterior surface of the MEMS device to expose a portion of the MEMS device;
etching the exposed portion of the MEMS device to form a step-shaped portion on the exterior surface of the MEMS device;
removing the photoresist on the exterior surface of the MEMS device;
forming a conductive layer on the exterior surface of the MEMS device including the step-shaped portion; and
dicing through a portion of the step-shaped portion and through the semiconductor layer to form at least two separate stacked devices.

17. The method of claim 16 further comprising positioning one stacked device of the two separate stacked device on a package substrate.

18. The method of claim 17, wherein the package substrate includes a wirebond pad, and wherein the method further includes attaching a wire from the step-shaped portion of the one stacked device to the wirebond pad.

19. The method of claim 18 further comprising attaching another wire from the semiconductor layer to the wirebond pad.

20. The method of claim 19, wherein the wirebond pad provides a ground to the MEMS device of the one stacked device and the semiconductor layer.

21. The method of claim 20 further comprising forming a molding compound over the wirebond pad of the package substrate and further on the step-shaped portion of the MEMS device.

22. The method of claim 16, wherein the MEMS device is eutetically bonded to the semiconductor layer.

23. The method of claim 16, wherein the MEMS device includes a cap layer and a MEMS device layer, and wherein the step-shaped portion is formed in the cap layer, and wherein the cap layer includes a cavity formed therein.
